(19) United States
(12) Patent Application Publication
(10) Pub. No.: US 2004/0011962 A1
(43) Pub. Date: Jan. 22, 2004

(54) Multicycle integration focal plane array (MIFPA) for lock-in (LI-), gated (G-), and gated lock-in (GLI-) imaging, spectroscopy and spectroscopic imaging

(76) Inventors: Ken K. Chin, Pine Brook, NJ (US); Haijiang Ou, Edison, NJ (US)

Correspondence Address: Dr. Ken K. Chin, 3 Le Mans Place, Pine Brook, NJ, 07058, US

(21) Appl. No.: 09/973,710

(22) Filed: Jul. 18, 2002

(51) Int. Cl. H01L 25/00

(52) U.S. Cl. 250/370.08

(57) ABSTRACT

The present invention comprises the principle, theory, circuit design, computer simulation, and experimental demonstration of a new type of electronic device—the multi-cycle integration focal plane array (MIFPA)—for lock-in and/or gated imaging, spectroscopy, and/or spectroscopic imaging of extremely weak signals buried in strong background. Particularly, the MIFPA can operate in three modes—the lock-in (LI), gated (G), and gated lock-in (GLI) modes. Particularly, one MIFPA circuitry was demonstrated by simulation and experiment. Particularly, the circuitry was capable to perform the LI-, G-, and GLI-modes.

### BACKGROUND OF THE INVENTION

1. Field of the Invention

This invention relates to the theory, design, performance, and applications of a new electronic device—a new type of staring focal plane array (FPA), which utilizes the method of multicycle integration (MI) to acquire the signal. The new device is called multicycle integration focal plane array (MIFPA). MIFPA makes lock-in amplification and boxcar-gated integration, which work so far only for a single detector, feasible for array configuration. MIFPA has three modes of operation—lock-in (LI), gated (G), and gated lock-in (GLI) modes. The application of MIFPA is in the detection of extremely weak imaging, spectroscopic, and spectroscopic imaging.

2. Description of Prior Art

In the past few decades, the lock-in amplifier and boxcar-gated integrator have played important roles in the detection of extremely weak signals buried in strong background noises. However, the lock-in amplifier and boxcar-gated integrator, being sophisticated electronics systems, work only for a single detector. For array detectors, either linear or area, for imaging, spectroscopic, and spectroscopic imaging applications, the staring focal plane arrays (FPA) were invented. In the existing FPA technology, each pixel has a semiconductor photodiode, the photocurrent (signal plus background) of which goes through single-cycle integration (SI). When signal is extremely weak in comparison with background, the signal to noise ratio, dynamic range, and other criteria of performance of the existing single-cycle integration focal plane array (SIFPA) are limited by its integration time. It cannot achieve the level of performance of the lock-in amplifier. By replacing the FPA's single-cycle integration (SI) with multi-cycle integration (MI), we turn SIFPA into MIFPA. MIFPA can operate in three modes—lock-in (LI), gated (G), and gated lock-in (GLI) modes. LI-MIFPA and G-MIFPA incorporate the concepts of lock-in amplifier and gated integrator into the array configuration, respectively. LI-MIFPA can perform lock-in imaging, spectroscopy, and or spectroscopic imaging. G-MIFPA can perform gated imaging, spectroscopy, and or spectroscopic imaging. GLI-MIFPA has the features of both LI-MIFPA and G-MIFPA.

### SUMMARY OF THE INVENTION

A new type of focal plane array (FPA)—multi-cycle integration focal plane array (MIFPA)—has been invented for lock-in, gated, or gated lock-in detection of extremely weak image and/or spectroscopic signals buried in strong background. The principles, theory, circuit designs, computer simulation, fabrication, and experimental results of the MIFPA are presented. The total signal integration time of the MIFPA is several orders greater than the single-cycle integration focal plane array (SIFPA), which is the existing FPA technology. As a result, the sensitivity of weak signal detection, the dynamic range, and other criteria of performance of the MIFPA are several orders better than those of the SIFPA. In addition, the MIFPA also reduces significantly low-frequency noises. This essential feature of MIFPA is the reason why MIFPA is far better than the widely used method of multi-image (acquired by the existing SIFPA technology) averaging using image processing software, which inevitably includes the low frequency noise and other noises associated with the multiple utilization of the A/D converter of the data acquisition system. The MIFPA can operate in three modes—the lock-in (LI), gated (G), and gated lock-in (GLI) modes.

In LI-MIFPA, radiation from the scene or object, and therefore the signal photocurrent, is modulated either passively or actively, while dark and/or background currents are not. By using a correlated multi-cycle integrator, the signal current is accumulated while the dark or background current is cancelled. As a result, the total integration time for each pixel is increased by several orders, and so is the improvement of the imager's signal to noise ratio and dynamic range. In G-MIFPA, the direction of integration of the correlated multi-cycle integrator does not change as in the BC-MIPFA. The integrator is triggered on by the arrival of the pulse of signal photocurrent, and turned off after the pulse disappears. It remains inactive until its trigger by the arrival of the next pulse of signal photocurrent. The LI-mode is used for the detection of extremely weak constant signal. The G-mode is appropriate for periodically arrived (for example, a pulsed-laser excited fluorescence spectroscopy) short photocurrent pulses. The GLI-mode is for periodical pulsed signal, which is buried under strong background, and therefore the principles of both LI-mode and G-mode are utilized.

MIFPA is a generic electronic device that can be used for imaging, spectroscopy, and/or spectroscopic imaging. It is valid for any source of signals, including photonic, electrical, magnetic, and thermal. The principles and circuit designs of MIFPA can be used as long as the signal is extremely weak and/or short in comparison to the background. It is not limited by the specific method of lock-in and/or gating, neither is it by the type of detectors.

### BRIEF DESCRIPTION OF THE SYMBOLS AND DRAWINGS

| 1. | Definition of Symbols |
|---|---|
| Iₛ | DC image signal photocurrent generated in the detector by the scene of imaging. Iₛ is defined |
| | as the average of the real image signal current iₛ, which is time varying, through its integration |
| | cycle. |
| I_{d} | DC dark current thermally generated. I_{d} is defined as the average of the time-varying real dark |
| | current i_{d}. |
| I_{b} | DC background current, which is generated by photons of the same wavelengths under |
| | detection. As Iₛ and I_{d}, I_{b} is defined as the average of the time varying real background current |
| | i_{b}. When I_{b} can be modulated separately from signal current Iₛ, the background current I_{b} plays |
| | the same role as the dark current I_{d}. In this invention, we treat I_{b} and I_{d} as equivalent, using I_{b} to |
| | denote both of them. |
| e | charge of an electron, 1.6 × 10⁻¹⁹ C. |
| Nₛ | number of integrated photoelectrons generated by a steady signal photon flux. |
| $\overline{{n}_{ro}^{2}}$ | noise due to readout electronics. |
| $\overline{{n}_{1 / f}^{2}}$ | 1/f or low frequency noise mostly associated with the fabrication process of the photodetector. |
| $\overline{{n}_{th}^{2}}$ | detector thermal noise. |
| $\overline{{n}_{s}^{2}}$ | shot noises associated with the steady signal current. |
| $\overline{{n}_{b}^{2}}$ | shot noises associated with the steady background current. |
| $\sqrt{\overline{{n}_{b}^{2}}}$ | root mean square (rms) value of background current generated shot noise, which is the predominant noise source under the condition of Iₛ << I_{b}. |
| Nₛₐₜ | saturation or maximum number of electrons that an integration capacitor can handle. |
| m | number of integration cycles of the correlated multi-cycle integrator. |
| τ | period of each cycle of integration for lock-in MIFPA. |
| τₒₙ | gate-on or integration duration time for gated or gated lock-in MIFPA. |
| τ_{off} | gate-off or non-integration duration time for gated or gated lock-in MIFPA. |
| α | $weigh of gate \text{-} on duration , defined as α = \frac{{τ}_{on}}{τ} = \frac{{τ}_{on}}{{τ}_{on} + {τ}_{off}}$ |
| Tᵢ | Total integration time. |
| | For LI- MIFPA, Tᵢ = mτ; |
| | For G-MIFPA and GLI-MIFPA, Tᵢ = mατ = mτₒₙ. |
| R | Signal to noise ratio, defined as $R = Signal / Noise = \frac{{N}_{s}}{\sqrt{\overline{{n}^{2}}}} ,$ where Nₛ is the number of electrons due to the signal current Iₛ, and \overline{n²} is the root mean square value of the total number of electrons due to random noise. |
| D | Dynamic range in decibels, defined as D = 20 log₁₀Rₘₐₓ, when the maximum integration time is |
| | utilized. |
| f | Frequency. |
| m | number of integration cycles of MIFPA |
| ω | Angular frequency. ω = 2πf |
| ωₘ | Modulation frequency. ωₘ = 2πfₘ = 2π/τ. |
| T (ω) | Noise transmission window of a conventional single cycle integrator for a conventional FPA get,0008 where Vₒ(ω, φ) is the output voltage of the integrator with a unit harmonic current i(t) = e^{j(ωt+φ)} as the input. |
| Tₘ(ω) | Noise transmission window of a correlated multi-cycle integrator for a LI-MIFPA |
| T_{P-L}(ω) | Transmission window of typical phase sensitive detector plus low pass filter |
| T_{LI}(ω) | Transmission window of typical single detector lock-in amplifier |
| H_{L}(ω) | Transfer function of low pass filter |
| H_{S}(ω) | Transfer function of signal channel |

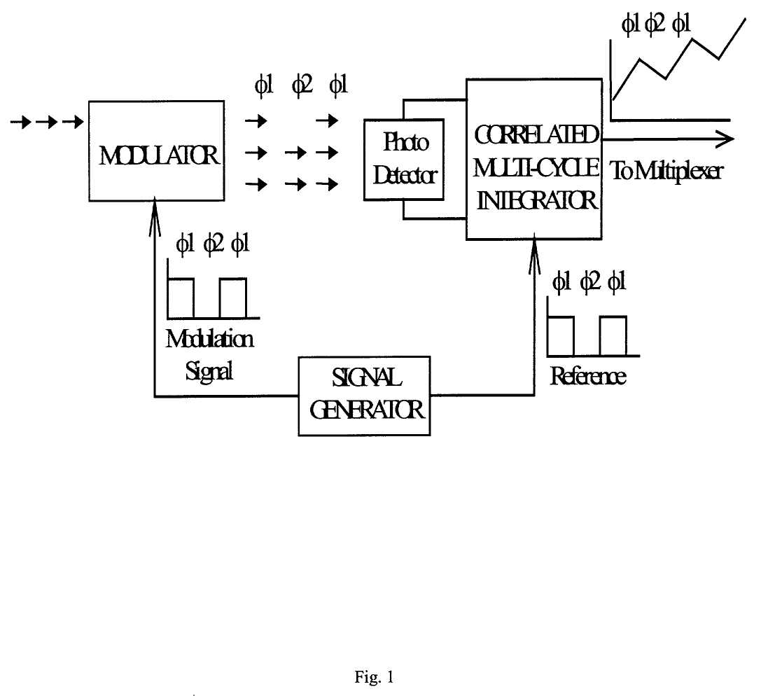

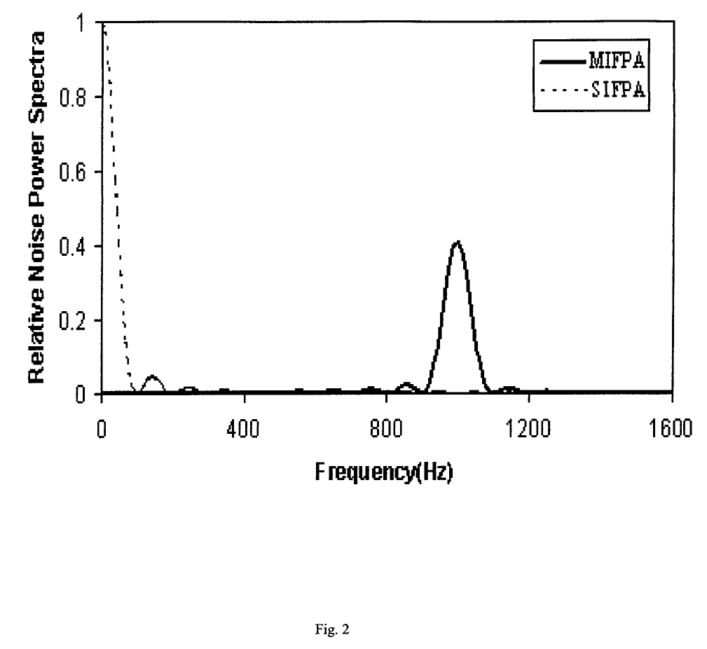

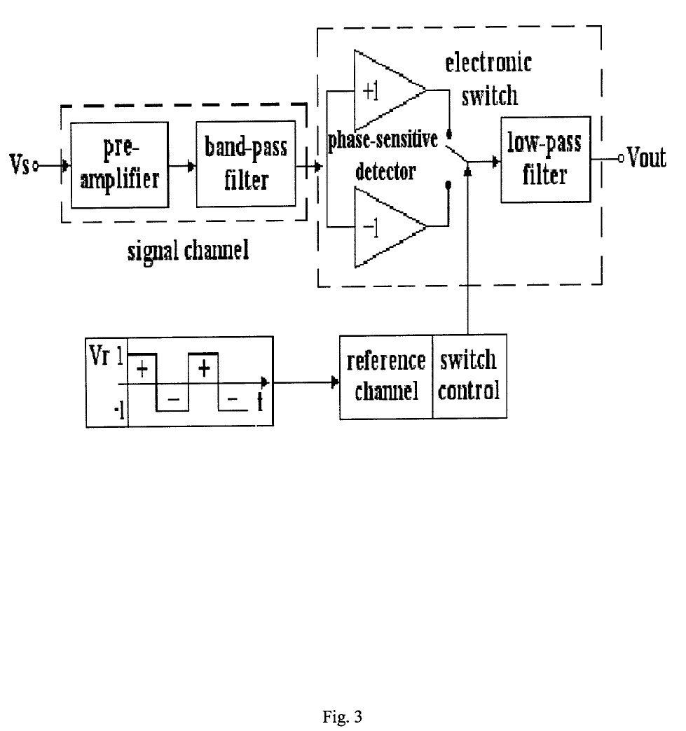

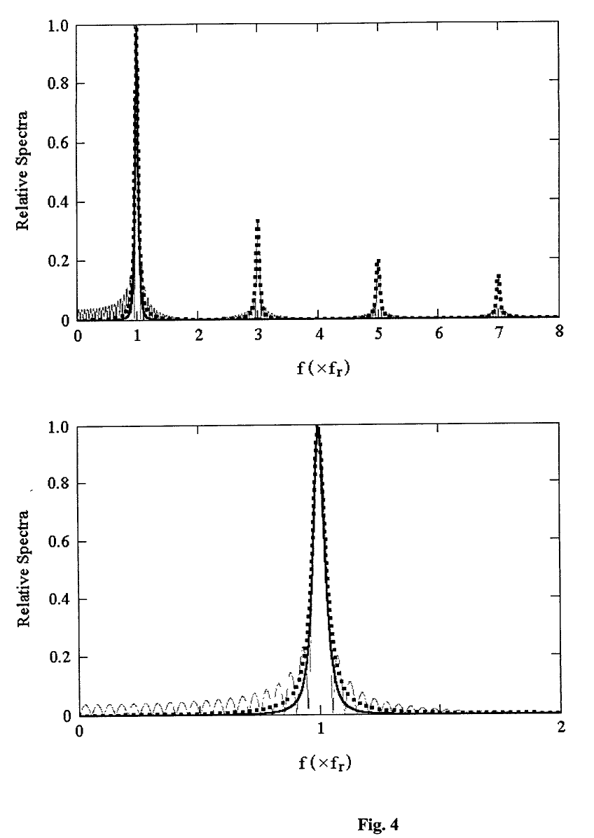

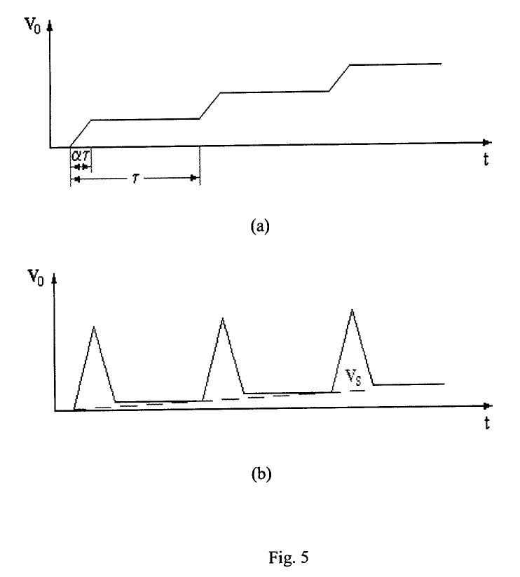

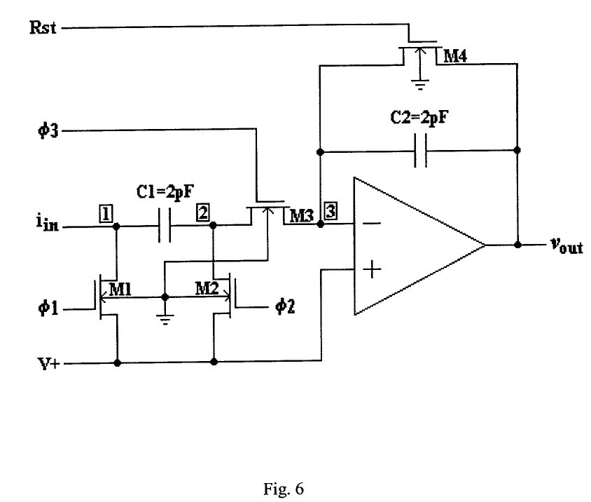

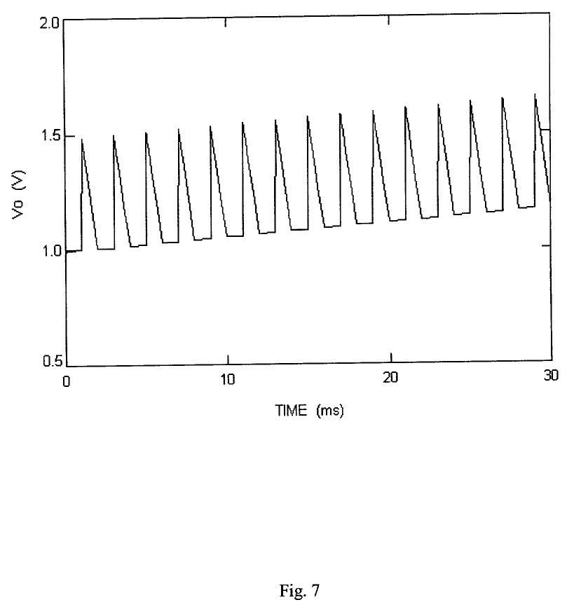

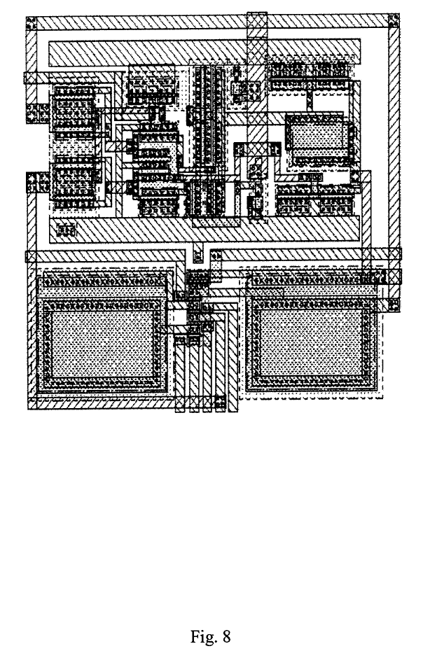

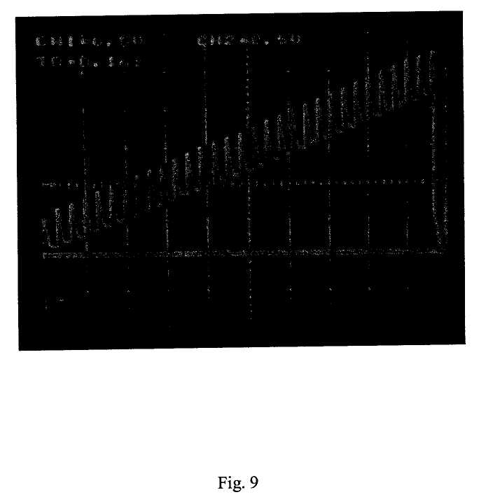

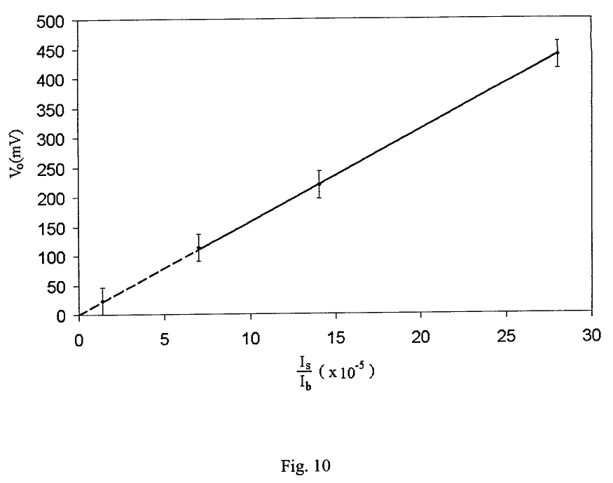

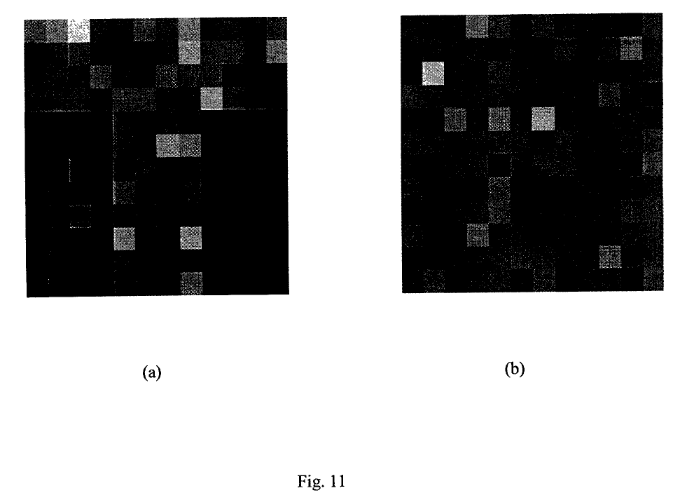

2. List of Figures

| | |
|---|---|
| FIG. 1 is | The Principles of Lock-In Multicycle Integration Focal Plane |
| | Array (LI-MIFPA) |
| FIG. 2 is | Relative Noise Power Spectra of Integrators |
| | Solid Curve: Tₘ²(ω) of a correlated multi cycle integrator |
| | used in MIFPA |
| | Dashed Curve: T²(ω) of a single cycle integrator used in |
| | SIFPA |
| FIG. 3 is | Block Diagram of Lock-in Amplifier |
| FIG. 4 is | Transmission Windows of MIFPA, PSD + LPF, and Lock-in |
| | Amplifier |
| FIG. 5 is | Principles of Gated Multicycle Integration Focal Plane Array |
| | (G-MIFPA) and Gated |
| | Lock-in Multicycle Integration Focal Plane Array |
| | (GLI-MIFPA) |
| | (a) Gated Multicycle Integration |
| | (b) Gated Lock-in Multicycle Integration |
| FIG. 6 is | Schematic of the Circuit Design of Correlated Multi-Cycle |
| | Integrator of MIFPA |
| FIG. 7 is | Computer Simulation Results of the Correlated Multi-Cycle |
| | Integrator |
| FIG. 8 is | The Layout of VLSI Design of the Silicon Chip with MIFPA |
| | Circuitries |
| FIG. 9 is | Experimental Results of the Correlated Multi-Cycle Integrator |
| | of MIFPA |
| FIG. 10 is | Experimental Results of the Sensitivity of LI-MIFPA |
| FIG. 11 is | (a) Lock-in Imaging Using MIFPA |
| | (b) Conventional Imaging Using SIFPA |

### DETAILED DESCRIPTION OF THE INVENTION

During the course of this description, like numbers will be used to identify like elements according to different figures which illustrate the invention.

1. Deficiencies of Existing FPA Technology for Detecting Weak Signals

The lock-in (LI) amplifier and gated integrator (GI) have been playing important roles in the detection of weak photon signals. They were developed for a single photodetector. For the focal plane array (FPA) or image sensor, which utilizes a staring linear or area array of photodetectors to simultaneously detect an array of photon signals, the periodic integration of photocurrent is used to improve signal to noise ratio. The sensitivity of a semiconductor photodetector is characterized by its signal to noise (voltage or current) ratio R

$$R = Signal / Noise = \frac{{N}_{s}}{\sqrt{\overline{{n}_{ro}^{2}} + \overline{{n}_{1 / f}^{2}} + \overline{{n}_{th}^{2}} + \overline{{n}_{s}^{2}} + \overline{{n}_{b}^{2}}}} \qquad ( 1 )$$

where N, is the number of integrated photoelectrons generated by a steady signal photon flux, and the denominator is the root mean square (rms) value of the total number of noise electrons. The noise electrons are from various sources. \overline{nᵣₒ²} is the noise due to readout electronics, \overline{n_{1/f}²} the 1/f or low frequency noise mostly associated with the fabrication process of the photodetector, \overline{nₜₕ²} the detector thermal noise, and \overline{nₛ²} and \overline{n_{b}²} the shot noises associated with the steady signal and background currents, respectively. Note that the DC background current I_{b} and dark current I_{d} have the same effect. We use I_{b} to represent the sum of I_{b} and I_{d}, and \overline{n_{b}²} to represent the rms value of the number of noise electrons associated with I_{b} and I_{d}. When I_{b} (DC) is several orders greater than signal current Iₛ (DC), the shot noise \overline{n_{b}²} may be predominant among all the components of the noise electrons. Therefore, Eq. (1) can be simplified as

$$R = Signal / Noise \approx \frac{{N}_{s}}{\sqrt{\overline{{n}_{b}^{2}}}} = \frac{{N}_{s}}{\sqrt{{N}_{b}}} = \frac{{I}_{s}}{\sqrt{e {I}_{b}}} \sqrt{{T}_{i}} \qquad ( 2 )$$

where N_{b} is the number of integrated electrons due to DC background and/or dark current I_{d}, e the electron charge, Tᵢ the signal integration time (approximately equal to the frame period for a staring FPA). Here we use the equation

$$\overline{{n}_{b}^{2}} = {N}_{b} = \frac{{I}_{b} {T}_{i}}{e} \qquad ( 3 )$$

which is valid for photovoltaic detectors. If the detectors are photoconductors, such as QWIP's, the rms value

$$\sqrt{\overline{{n}_{b}^{2}}}$$

of background current generated shot noise electrons as expressed by Eq. (3) will be multiplied by a factor of square root of 2. Other equations in the following discussion will be modified with a similar factor of correction, which does not affect substantially our conclusions of MIFPA.

Eq. (2) indicates that the signal to noise ratio is proportional to the square root of integration time Tᵢ of each pixel. However, T is limited by Nₛₐₜ, the saturation or maximum number of electrons that an integration capacitor can handle. Note that Nₛₐₜ is limited by two factors. First, the capacitance can only be in the range of pF due to real estate limit in the FPA; secondly, the increase of the capacitance will induce a higher kTC noise. All the existing FPA technologies use single-cycle integration (SI) of signal (note that in the case of gated intensified CCD imaging system the FPA still operates in SI mode). For the CMOS FPA, the capacitance trans-impedance amplifier (CTIA) is the most widely used readout interface. Thus

$${T}_{i} = \frac{e {N}_{sat}}{{I}_{s} + {I}_{b}} \approx \frac{e {N}_{sat}}{{I}_{b}} \qquad ( 4 )$$

Using signal integration time defined by Eq. (3), we can obtain the optimized signal to noise ratio for the existing single-cycle integration focal plane array (SIFPA) technology using CTIA

$${R}_{SIFPA , opt} = {( Signal / Noise )}_{SIFPA , max} \approx \frac{{I}_{s}}{{I}_{b}} \sqrt{{N}_{sat}} \qquad ( 5 )$$

Assuming R_{SIFPA,opt}=1, we have the theoretical minimum detectable signal current to background current ratio for a SIFPA

$${( {I}_{s} / {I}_{b} )}_{SIFPA , min} \approx \frac{1}{\sqrt{{N}_{sat}}} = 1.63 \times {10}^{- 4} \qquad ( 6 )$$

where we assume that the integrator has a storage capacitor with capacitance of 2 pF and saturation voltage of 3V. Apparently, the existing FPA technology of single-cycle integration (SI) is inadequate to deal with many cases, in which the signal photocurrent to background current ratio Iₛ/I_{b} is extremely low, such as visible and infrared (IR) solar magnetography (<10⁻⁴), liquid nitrogen temperature imaging using long wave length infrared (LWIR, 8-12μ)) quantum well infrared photodetector (QWIP) array, 15μ very long wavelength (VLWIR) imaging in space (10⁻⁶˜10⁻⁵), Raman spectroscopy with near infrared (NIR) excitation, and VLWIR spectroscopic imaging of biomedical specimens (<10⁻⁶).

2. Principles of Multicycle Integration Focal Plane Array (MIFPA)

For extremely weak signal detection, by replacing single-cycle integration (SI) with multicycle integration (MI), we can increase the integration time by several orders, and therefore dramatically improve the performance of the FPA, including (but not limited to) sensitivity and dynamic range. The multicycle integration focal plane array (MIFPA) can operate in lock-in (LI), gated (G), and gated lock-in (GLI) modes.

2.1. Lock-In Multi-cycle Integration Focal Plane Array (LI-MIFPA)

Each pixel of the LI-MIFPA has a correlated multicycle integrator, which accumulates the signal while canceling the background. The principles of background cancellation of the LI-MIFPA are shown in FIG. 1.

The schematic shown here is for the simplest and most common case. A passive optical modulator, which can be a mechanic chopper, an electric-optical switch, a polarizer, or other devices, is placed in front of the photodetector to modulate the photon flux from the scene or object for imaging, spectrum, or spectroscopic imaging. The signal can also be actively modulated, in which the signal photon flux is generated by modulated power source, such as a pulse laser. When the modulator is on in one phase (φ1 in the figure), the current generated by the detector will be the signal photocurrent Iₛ plus the DC background current I_{b} from the radiation not modulated. When the radiation from the imaging target is blocked by the modulator in another phase φ2 of equal duration as φ1, only the DC I_{b} is present. By controlling the correlated multicycle integrator synchronically with the modulation control signal, the integrator charges the capacitor with the signal and background currents in φ1, but discharges it with background current only in φ2. Discharged by the background current in each cycle, the capacitor is saved for signal current integration, and the total integration time is increased. The advantages of BC-MIFPA over SIFPA are:

2.1.1. Advantages of Lock-In Multi-cycle Integration Focal Plane Array (LI-MIFPA)

(a) Improvement of Signal to Noise Ratio

In BC-MIFPA, Eq. (4) is replaced by

$$T \approx \frac{e {N}_{sat}}{{I}_{s}} \qquad ( 7 )$$

Using signal integration time defined by (6), we can obtain the optimized signal to noise ratio for

$${R}_{MIFPA , opt} = {( Signal / Noise )}_{MIFPA , max} \approx \sqrt{\frac{{I}_{s}}{2 {I}_{b}}} \sqrt{{N}_{sat}} \qquad ( 8 )$$

The improvement of signal to noise ratio is a factor of

$$\sqrt{\frac{{I}_{b}}{2 {I}_{s}}} \qquad ( 9 )$$

Assuming R_{MIFPA,opt}=1 in (7), for the same integration capacitance and saturation voltage, we have BC-MIFPA's theoretical minimum detectable signal to background ratio

$${( \frac{{I}_{s}}{{I}_{b}} )}_{MIFPA , min} \approx \frac{2}{{N}_{sat}} = 5.04 \times {10}^{- 8} \qquad ( 10 )$$

A comparison of (10) and (6) shows that the BC-MIFPA improves the weakest detectable signal, as well as signal to noise ratio, by more than three orders.

(b) Improvement of Dynamic Range

In addition to signal to noise ratio and weakest detectable signal, another important figure of merit of a focal plane array is its dynamic range. In terms of decibels, the dynamic range D of a conventional SIFPA is

$${D}_{SIFPA} = 20 {log}_{10} {R}_{SIFPA , max} = 20 {log}_{10} ( \frac{{I}_{s}}{{I}_{b}} \sqrt{{N}_{sat}} ) \qquad ( 11 )$$

whereas for a MIFPA it is

$${D}_{MIFPA} = 20 {log}_{10} ( \sqrt{\frac{{I}_{s} {N}_{sat}}{{I}_{b}}} ) \qquad ( 12 )$$

The improvement of dynamic range is

$${D}_{MIFPA} - {D}_{SIFPA} = 20 {log}_{10} ( \sqrt{\frac{{I}_{b}}{{I}_{s}}} ) \qquad ( 13 )$$

If I_{b}/Iₛ>10⁴ as in the case of solar magnetography, improvement of dynamic range will be more than 37 dB.

(c) Suppression of Low Frequency Noise

As shown in FIG. 1, in the method of BC-MIFPA both the signal and background are fed to the correlated multicycle integrator. The noise current generated in the detector also goes through the correlated multicycle integrator. The noise transmission window of the correlated multicycle integrator is

$${T}_{m} ( ω ) = \sqrt{{V}_{o} ( ω , φ ) {V}_{o}^{*} ( ω , φ )} = \frac{T}{C} \vert \frac{tan ( \frac{ω T}{4 m} ) sin ( \frac{ω T}{2} )}{\frac{ω T}{2}} \vert \qquad ( 14 )$$

where T is the total integration time, m the modulation frequency, and C the charge storage capacitor. For comparison, also shown in FIG. 2 is the noise transmission window (15) of a single-cycle integrator used in a conventional SIFPA

$$T ( ω ) = \sqrt{{V}_{o} ( ω , φ ) {V}_{o}^{*} ( ω , φ )} = \frac{\vert 2 sin ( \frac{ω T}{2} ) \vert}{ω C} \qquad ( 15 )$$

In both cases, the rms value of the total number of noise electrons is the same

$$\sqrt{\overline{{n}_{b}^{2}}} = \sqrt{\overline{{V}_{n}^{2}}} \frac{C}{e} = {\frac{C}{e} [ {\int }_{0}^{∞} {T}^{2} ( ω ) w ( f ) ⅆ f ]}^{1 / 2} = \sqrt{{I}_{b} T / e} = \sqrt{{N}_{b}} \qquad ( 16 )$$

for the same total integration time. Comparing the two spectra of FIG. 2, however, we note that the transmission function T (ω) of a single-cycle integrator is that of a low pass filter with bandwidth equal to 1/2T, while the transmission function of the correlated multicycle integrator is that of a band pass filter peaked at the modulation frequency c, with satellite windows centered at the odd harmonics of ωₘ. An apparent advantage of LI-MIFPA then lies in its capability of suppressing the flicker or 1/f noise, which, among all the noise sources, is usually important, and even dominant for some types of widely used detectors, such as InGaAs, InSb, and HgCdTe IR photodetectors.

(d) On-Chip Data Processing

In current FPA technology, multi-image (up to 10,000 images in solar magnetography) averaging with image processing software is utilized to extract extremely weak signal buried in strong background. Even with the help of dithering, this averaging method is limited and unreliable. In contrast, BC-MIFPA perforrns various functions of on-chip data processing, including addition, subtraction, averaging, and direct extraction of useful signals. As a recent trend in the development of FPA, direct on-chip data processing is preferred because of its efficiency. We can effectively avoid the system limitations imposed by the slow speed and statistical errors imposed by the high precision analog to digital converter. In addition, SIFPA's multi-image averaging will inevitably include the 1/f noise, which is eliminated by MIFPA.

2.1.2. Comparison of Lock-in MIFPA and Conventional Lock-in Amplifier

The block diagram of a basic lock-in amplifier is shown in FIG. 3. The key components are the phase sensitive detector (PSD), which demodulates the modulated signal to recover the signal as DC or low frequency components, and the low pass filter (LPF), which reduces the bandwidth of the noise (the signal as well), recovering weak signals buried in strong noise. In frequent domain \overline{ω}, a unit harmonic input fed to the PSD leads to an output from the LPF

$${V}_{out} ( ϖ ; ω , φ ) = \frac{2}{πj} {ⅇ}^{j φ} {\sum }_{k = - ∞}^{∞} \frac{1}{2 k + 1} δ [ ϖ - ( 2 k + 1 ) {ω}_{m} - ω ] {H}_{L} ( ϖ ) \qquad ( 17 )$$

where ω and φ are the frequency and phase of the input, respectively, and H_{L} is the transfer function of the LPF. Note that the output Vₒᵤₜ, which depends on the input ω and φ, is expressed in the frequency domain \overline{ω}. Since the LPF of most lock-in amplifiers has a very narrow bandwidth, the output only has DC and low frequency terms. Neglecting cross talk terms H_{L}[ω+(2k+1)ωₘ]×H_{L}[ω+(2k′+1)ωₘ], and following (14), we can calculate the transmission window of the PSD+LPF as a function of the input frequency

$${T}_{P - L} ( ω ) = {\sum }_{k = 0}^{∞} \frac{2}{( 2 k + 1 ) π} \vert {H}_{L} [ ω - ( 2 k + 1 ) {ω}_{m} ] \vert \qquad ( 18 )$$

In addition to PSD+LPF, the typical lock-in amplifier has a pre-amplifier and a band pass filter in its signal channel. The pre-amplifier brings the small signal to a level sufficient to overcome the noise induced by the PSD, which is a switch that generates noises at various frequencies. The band-pass filter rejects unnecessary interference and noise by filtering out the satellite peaks of (19). Therefore the transmission window of the lock-in amplifier is a single peak centered at the modulation frequency, with its bandwidth defined by the LPF

$${T}_{L I} ( ω ) = \frac{2}{π} \vert {H}_{L} ( ω - {ω}_{m} ) \vert \times \vert {H}_{S} ( ω ) \vert \qquad ( 19 )$$

where Hₛ(ω) is the transfer function of the signal channel. For comparison, (18), (19), and (14) are plotted in FIG. 4. Note that in FIG. 2, we plot (14) from 0 to the range of ωₘ, while in FIG. 4, we plot (14) for the whole wide range of spectrum, revealing its double satellite structure.

The critical component of LI-MIFPA is correlated multicycle integrator, which is a combination of phase sensitive detector and integrator. Since the integrator is a special type of low pass filter, LI-MIFPA is a special version of PSD+LPF. As shown in FIG. 4, (18) of the PSD+LPF of a typical lock in amplifier, which uses a second order RC low pass filter, and (14) of the LI-MIFPA have the similar feature of satellite peaks. The difference of (18) and (14) is in the sub-satellite peaks of the LI-MIFPA. Unlike the second order RC low pass filter, the transfer function of the integrator in LI-MIFPA has satellite peaks.

2.2. Gated Multicycle Integration Focal Plane Array (G-MIFPA)

MIFPA can also operate in gated (G) mode when signals appear in short pulses. In each cycle of integration with period r the on-time of the integrator is much shorter than the off-time (α<<1, FIG. 5). The G-MIFPA can operate without (FIG. 5.a) or with (FIG. 5.b) background cancellation. The device operates as the gated lock-in multicycle focal plane array (GLI-MIFPA) when it is programmed to perform background subtraction.

2.2.1. Simple Gated Multicycle Integration Focal Plane Array (G-MIFPA)

G-MIFPA is used when the number of integrated signal electrons is many orders smaller than that of the background and/or dark current electrons (αIₛ<<I_{b}, but αIₛ is not<<I_{b}, as in the case of IR fluorescence spectroscopy using nano-second pulse laser excitation), In G-MIFPA the direction of integration of the correlated multicycle integrator does not change as in the LI-MIPFA. The integrator is turned on by a trigger signal from the gate control circuit to integrate the signal photocurrent pulse, and turned off after a certain increment of time. It remains inactive until it is triggered again for the next signal pulse (FIG. 5.a). By keeping the integrator off we can avoid the shot noise when there is no signal.

2.2.2. Gated Lock-in Multicycle Integration Focal Plane Array (GLI-MIFPA)

If the signal is not only short, but is also associated with a much stronger background (in comparison with the background during the signal-off time, as in the case of LWIR spectroscopy using nano-second pulse laser excitation),

α<<1 (20)

Iₛ<<I_{b} (21)

then GLI-MIFPA can be used. In GLI-MIFPA, the correlated multicycle integrator of the GLIMIFPA goes through three phases (FIG. 5.b). In φ1, which lasts ατ, the integrator integrates both the signal pulse and strong background currents. In φ2, which has the same duration as φ1, the integrator reverses its direction of integration, and cancels the background of φ1. In φ3, which lasts much longer than φ1 or φ2, the integrator is turned off. The GLI-MIFPA combines the advantage of the G-mode—reduction of the on-time of the integrator to increase the integration time—and that of the LI mode—cancellation of background to increase the integration time.

3. Feasibility of MIFPA

3.1. MIFPA Circuit Design

The only difference of the conventional SIFPA and MIFPA is their integrator. The success of lock-in imaging using MIFPA depends on the circuit design of its correlated multicycle integrator, which must have as few devices as possible so that it can be incorporated into the array format. FIG. 6 is one the circuit designs of the correlated multicycle integrator, which uses four switches but only one operational amplifier to perform the required correlated multicycle integration of photocurrent. As shown in FIG. 6, in one phase, switch S2 is on while S1 and S3 are off. The input current is integrated on C1. At the end of the phase, by turning off S2 then turning on S1 and S3, the charges accumulated on C1 are transferred to C2. In the next phase, S1 and S2 are off while S3 is on. The input current is directly integrated on C2. It is readily seen that any background current will be cancelled in two successive phases.

Compared with the conventional SIFPA, which also needs the reset switch S4, MIFPA only needs one extra capacitor C1 and three additional MOS switches S1, S2, and S3 to perform the critical function of correlated multicycle integration. Considering the overall complexity of the circuitry of FPA, these extra components do not impose too great a technological challenge. Furthermore, for MIFPAs with a large number of pixels, the operational amplifier in FIG. 6 can be replaced by an amplifier plus a source follower. Our calculation shows that the amplification required is only a few hundreds.

3.2. MIFPA Circuit Simulation

FIG. 7 is a computer simulation result of the Correlated Multicycle Integrator designed for MIFPA, by using the circuit simulation package HSPICE. 25 cycles of integration, with a total integration time of 5 ms, are shown in the figure. With the level of background current as shown in FIG. 7, the maximum integration time will be less than 0.5 ms if a single cycle integrator is used.

3.3. MIFPA Circuit Fabrication

FIG. 8 is part of the layout of VLSI design of the silicon CMOS IC, which has various MIFPA circuitries, including single pixels, and linear and area arrays with multiplexers, as well as device parameter test fixtures. The figure shows one pixel of MIFPA, including both Versions I and III of the correlated multicycle integrator. The chip was designed using HP's 0.5μ CMOS design rules, and fabricated at HP's 0.5μ CMOS facility, which was managed by MOSIS.

4. Experimental Results of MIFPA

Three categories of experimental testing were performed on the MIFPA chip. FIG. 9 is a photocopy of the graph taken from the screen of a tracer, which is used to test the design of the correlated multicycle integrator as shown in FIG. 6. The Pulse Instrument Focal Plane Array Test Equipment setup is used to control the input and output of the Integrator. The modulation and correlated integration frequency of 31.25 kHz is generated by a pulse generator. With 30 cycles, a total time of 960 μs is used for integration. The data of test results were fed to a tracer. The output of the integrator has exactly the same features as the simulation results shown in FIG. 7. It is therefore demonstrated experimentally that the Correlated Multi-Cycle Integrator functions as designed.

To test MIFPA's sensitivity, signal to noise ratio, and dynamic range, a near infrared (NIR) light emitting diode (LED) powered by a DC source was used to generate the background photocurrent I_{b} 1.5×10⁻⁸ A, which was equivalent to a constant dark current I_{d} of the same magnitude in the NIR photodetector. A second NIR LED of the exact same characteristics, which was connected to a programmable square wave power supply with the same peak voltage as the DC power source of the first NIR LED. The second NIR LED generated modulated signal photocurrent Iₛ in the NIR photodetector. By adjusting the positions of the two LED's with respect to the photodetector, we can control the ratio of Iₛ/I_{b}. FIG. 10 shows the MIFPA output voltage Vₒ of the NIR photodiode as a function of the input Iₛ/I_{b}. The weakest signal measured in the experiment was (Iₛ/Iₛ)_{CMJ,,Measured}=7×10⁻⁵. Note that the measured output error bar due to random fluctuation is 23 mV, the predominant source of which is the shot noise of the photodetector. By extending the straight line, or the output voltage Vₒ as a function of the input Iₛ/I_{b}, as shown in FIG. 10, we conclude that the weakest detectable signal Iₛ/I_{b} in our experiment is

(Iₛ/I_{b})_{min, CMI,, Experimental}˜1.4×10⁻⁵ (22)

A comparison of (23) and (6) shows that under the same background, the weakest measurable signal using our testing MIFPA chip is more than one order smaller than the theoretical limit of the measurable signal using the conventional FPA of single-cycle integration. Since other widely used figures of merit of the FPA, such as signal to noise ratio, dynamic range, and non-uniformity caused fixed pattern noise, are related to each pixel's weakest detectable signal, therefore we conclude that we have experimentally demonstrated the feasibility of MIFPA technology. Note that the theoretical limit of Eq. (9) was not achieved, since we used only 2,000 cycles of integration and a small portion of the available saturation output voltage of 3 V to avoid saturation. Saturation could be caused by feed through of capacitors, slow drifting of CMOS device parameters, and other instabilities of the electronics involved. With improvement of stability and uniformity of our devices and electronics, we can use longer integration time for of each cycle, as well as more cycles of integration. As a result, a longer total integration time that is close to the theoretical limit can be implemented. We expect that the theoretical limit of the weakest detectable signal as depicted by Equation (10) will be approached with the maturity of MIFPA technology.

FIG. 11(a) is the image of an object, which is taken by a single pixel of our first working MIFPA test chip, instead of the array, to avoid pixel nonuniformity induced noise. It is a letter T composed of 80 bright squares out of a total of 144 squares. While the dark squares do not generate any photocurrent, each of the bright squares generates a signal photocurrent of 1.05×10⁻¹² A in the photodetector, which is equal to 7×10⁻⁵ of the background photocurrent 1.5×10⁻⁸ A. FIG. 11(b) is the “image,” or rather no image, of the same target under the same background (Iₛ=1.05×10⁻¹² A, unmodulated; and I_{b}=1.05×10⁻⁸ A) taken by the conventional imaging method of single-cycle integration. A comparison of FIGS. 11(a) and (b) clearly demonstrates the dramatic improvement MIFPA brings to the FPA technology of imaging and spectroscopy. Interestingly, we tried to “average” numerous figures (b) to obtain an image similar to (a). This widely used multi-image averaging method failed in our test.

1) A new type of focal plane array—multicycle integration focal plane array (MIFPA), linear or area, which, unlike the existing FPA of single-cycle integration, utilizes three additional MOS switches (M1, M2, and M3 of FIG. 1) and one additional capacitance (C1 of FIG. 1) for each pixel to perform on-chip multicycle integration.

2) Applications of MIFPA—to detect extremely weak signals for imaging, spectroscopy, and spectroscopic imaging.

3) Three operational modes of MIFPA—lock-in (LI-), gated (G-), and gated lock-in (GLI-) modes.

4) A new type of focal plane array—lock-in multicycle integration focal plane array (LI-MIFPA), linear or area, which possesses the following features:
a) it uses an active or passive modulator to modulate the signal;
b) it does not modulate dark and/or background current;
c) it uses a correlated multicycle integrator for each pixel, so that the signal current is accumulated while the background and/or dark current is cancelled;
d) the integration time of the LI-MIFPA can be many orders longer than that of the existing FPA technology;
e) therefore, the signal to noise ratio, dynamic range, and low frequency or 1/f noise of the LI-MIFPA can be improved by many orders in comparison with the existing FPA technology.

5) Applications of LI-MIFPA—to detect extremely weak signals for imaging, spectroscopy, and spectroscopic imaging.

6) A new type of focal plane array—gated multicycle integration focal plane array (G-MIFPA), linear or area, which has the same multicycle correlated integrator for each pixel as the LI-MIFPA, is programmed to operate in the gated mode, and possesses the following features:
a) it uses a pulsed light source to generate a repetitive signal (as in the case of IR fluorescence spectroscopy using nano-second pulse laser excitation);
b) the G-MIFPA is used when the number of integrated signal electrons is many orders smaller than that of the background and/or dark current electrons αIₛ<<I_{b}, but αIₛ is not<<I_{b};
c) in G-MIFPA the direction of integration of the correlated multicycle integrator does not change as in the LI-MIPFA; The integrator is turned on by a trigger signal from the gate control circuit to integrate the signal photocurrent pulse, and turned off after a certain increment of time;
d) the integration time of the G-MIFPA can be many orders longer than that of the existing FPA technology;
e) therefore, the signal to noise ratio, dynamic range, and low frequency or 1/f noise of the G-MIFPA can be improved by many orders in comparison with the existing FPA technology.

7) Applications of G-MIFPA—to detect extremely weak signals for imaging, spectroscopy, and spectroscopic imaging.

8) A new type of focal plane array—gated lock-in multicycle integration focal plane array (GLI-MIFPA), linear or area, which has the same multicycle correlated integrator for each pixel as the LI-MIFPA, is programmed to operate in the gated lock-in mode, and possesses the following features:
a) it uses a pulsed light source to generate a repetitive signal (as in the case of LWIR spectroscopy using nano-second pulse laser excitation);
b) the GLI-MIFPA is used when the signal is not only short, but is also associated with a much stronger background (α<<1, Iₛ<<I_{b});
c) in GLI-MIFPA, the correlated multicycle integrator goes through three phases (FIG. 5.b). In φ1, which lasts ατ, the integrator integrates both the signal pulse and strong background currents. In φ2, which has the same duration as φ1, the integrator reverses its direction of integration, and cancels the background of φ1. In φ3, which lasts much longer than φ1 or φ2, the integrator is turned off.
d) the GLI-MIFPA combines the advantage of the G-mode—reduction of the on-time of the integrator to increase the integration time—and that of the LI mode—cancellation of background to increase the integration time;
e) therefore, the signal to noise ratio, dynamic range, and low frequency or 1/f noise of the G-MIFPA can be improved by many orders in comparison with the existing FPA technology.

9) Applications of GLI-MIFPA—to detect extremely weak signals for imaging, spectroscopy, and spectroscopic imaging.

10) A new device—correlated multicycle integrator (comprising of one operational amplifier or source follower and four MOS switches), which can be programmed to control the MIFPA to operate in lock-in (LI-), gated (G-), or gated lock-in (GLI) mode.
